(19) United States
(12) Patent Application Publication
(10) Pub. No.: US 2025/0006524 A1
(43) Pub. Date: Jan. 2, 2025

(54) WAFER TEMPERATURE CONTROL DEVICE, WAFER TEMPERATURE CONTROL METHOD AND WAFER TEMPERATURE CONTROL PROGRAM

(71) Applicant: HORIBA STEC, Co., Ltd., Kyoto-shi (JP)

(72) Inventors: Daisuke HAYASHI, Kyoto-shi (JP); Kotaro TAKIJIRI, Kyoto-shi (JP)

(21) Appl. No.: 18/757,233

(22) Filed: Jun. 27, 2024

(30) Foreign Application Priority Data
Jun. 30, 2023 (JP) 2023-108407

(51) Int. Cl. H01L 21/67; G05D 16/20; G05D 23/30; H01L 21/66

(52) U.S. Cl. CPC H01L 21/67248; G05D 16/20; G05D 23/30; H01L 21/67109; H01L 22/12

(57) ABSTRACT

The present invention is a wafer temperature control device that includes a gas regulator that regulates a pressure or a flow rate of a gas, a temperature sensor that measures a temperature of either a measurement target area of a wafer or of an area adjacent thereto, an observer that, based on the measurement temperature from the temperature sensor and on a gas manipulated variable input into the gas regulator or the pressure or flow rate regulated by the gas regulator, estimates a temperature of a non-measurement target area that is different from the measurement target area of the wafer, and a gas control unit that, based on an estimation temperature for the non-measurement target area estimated by the observer and on a set temperature for the wafer, controls the gas manipulated variable input into the gas regulator using model predictive control.

### CROSS-REFERENCE TO RELATED APPLICATION

The present application claims priority from Japanese Patent Application No. 2023-108407 filed Jun. 30, 2023, which is incorporated herein by reference in its entirety.

### BACKGROUND OF THE INVENTION

### Technical Field

The present invention relates to a wafer temperature control device, a wafer temperature control method, and a wafer temperature control program.

### 2. Description of the Related Art

Conventionally, in a semiconductor manufacturing process such as, for example, film formation processing or the like, a processing subject in the form of a wafer is placed on a plate of an electrostatic chuck or the like. Here, the temperature of the plate of the electrostatic chuck or the like is regulated so that the temperature of the wafer is maintained at a predetermined set temperature.

Moreover, because the plate on which the wafer has been placed is then disposed in a low-pressure environment such as a vacuum inside a processing chamber or the like, as is shown in Patent Document 1, supplying a heat transfer gas such as helium gas or the like between the plate and the wafer may be considered in order to accelerate the heat transfer from the temperature-regulated plate to the wafer.

Here, because the rate of heat transfer varies depending on the pressure of the heat transfer gas supplied between the plate and the wafer, it is necessary for the pressure of the heat transfer gas to be regulated.

However, even if the pressure of the heat transfer gas is regulated, because of a variety of technical limitations, it is difficult to maintain the temperature of the wafer placed on the plate so that this temperature remains at a predetermined set temperature.

Here, measuring the temperature of a circumferential portion (for example, an edge portion) of a wafer where temperature measurement may be performed comparatively easily, and then controlling the wafer using this measurement temperature so that the wafer is maintained at a predetermined set temperature may be considered. However, because there is a difference in temperature between a central portion and a circumferential portion of a wafer, it is difficult to perform control so that the central portion of the wafer is maintained at a predetermined set temperature.

Note that performing temperature control by measuring the temperatures of both the central portion and the circumferential portion of a wafer might also be considered, however, in practical use, it is difficult to provide both a temperature sensor for measuring the central portion of a wafer and a temperature sensor for measuring the circumferential portion of a wafer inside a processing chamber.

### DOCUMENTS OF THE PRIOR ART

### Patent Documents

Patent Document 1: Japanese Patent No. 4034344

### SUMMARY OF THE INVENTION

The present invention was, therefore, conceived in order to solve the above-described drawbacks and it is an object thereof, in a device that controls the temperature of a wafer by regulating the pressure or flow rate of a gas, to enable the temperature of, for example, a non-measurement target area where temperature measurement is difficult, to be maintained at a set temperature by measuring, for example, the temperature of either a measurement target area where temperature measurement can be performed comparatively easily or an area adjacent thereto.

Namely, a wafer temperature control device according to the present invention is a wafer temperature control device in which a wafer is placed on a temperature-regulated plate and a gas is supplied between the plate and the wafer so as to control the temperature of the wafer, and that includes a gas regulator that regulates a pressure or a flow rate of the gas, a temperature sensor that measures a temperature of either a predetermined measurement target area of the wafer or an area adjacent thereto, an observer that, based on the measurement temperature from the temperature sensor and on a gas manipulated variable input into the gas regulator or the pressure or flow rate regulated by the gas regulator, estimates a temperature of a non-measurement target area that is different from the measurement target area of the wafer, and a gas control unit that, based on an estimation temperature for the non-measurement target area estimated by the observer and on a set temperature for the wafer, controls the gas manipulated variable input into the gas regulator using model predictive control.

According to a wafer temperature control device having the above-described structure, because the temperature of a non-measurement target area of a wafer is estimated using an observer that takes as input variables a measurement temperature of a measurement target area of the wafer or an area adjacent thereto, and a pressure or flow rate of a gas, it is possible to estimate the temperature of the non-measurement target area of a wafer with a sufficient level of accuracy. Moreover, because a gas manipulated variable input into the gas regulator is controlled using model predictive control based on an estimation temperature for the non-measurement target area estimated by the observer and on a set temperature for the wafer, it is simple to incorporate non-linear behavior of the rate of heat transfer from the plate to the wafer, and to accurately control the temperature of a non-measurement target area of the wafer so that this is maintained at a set temperature.

By combining an observer with model predictive control in this manner, it is possible to incorporate non-linear behavior in model predictive control, and it is no longer necessary to take non-linear behavior into account in an observer. Because of this, complicated modeling in order to incorporate non-linear behavior in an observer is rendered unnecessary, and it is possible to create an equation of state model in an observer far more simply. Moreover, by combining an observer with model predictive control, it is possible to accurately control the temperature of a non-measurement target area of a wafer simply by measuring the temperature of the measurement target area of the wafer. In other words, simply by measuring the temperature of one location of a wafer, it is possible to accurately control the temperature of another location thereof so that the usability of the wafer temperature control device is improved. In addition, by combining an observer with model predictive control, it becomes possible to perform robust control even of external disturbance generated by plasma or the like that injects heat into the wafer.

Here, ‘adjacent’ in reference to the temperature refers, for example, to a temperature of a component or space that is within a predetermined distance of a measurement target area of a wafer, and includes temperatures for which it is possible to construct a temperature model that shows a relationship between the temperature of a measurement target area and an adjacent temperature thereto. Moreover, ‘adjacent temperature’ additionally includes a temperature of a component that is in direct contact with a measurement target area of a wafer, a temperature of a space or a gas having a boundary face with a wafer, and a temperature of a component located at a distance of several μm from a wafer. Furthermore, ‘adjacent temperature’ may also include a temperature of a component that is able to conduct or transmit heat via at least one of conduction, convection, or radiation between itself and the measurement target area of a wafer.

Because a measurement target area of a wafer and a non-measurement target area thereof have a mutual thermal effect on each other, in order to accurately predict the temperature of a future non-measurement target area and then accurately control the temperature of this non-measurement target area, it is necessary that the temperature of the measurement target area be estimated with sufficient accuracy. For this reason, it is desirable that the observer estimate not only the temperature of the non-measurement target area but also a temperature of the measurement target area, and that the gas control unit control the gas manipulated variables input into the gas regulator using model predictive control based on the estimation temperature of the measurement target area and the estimation temperature of the non-measurement target area and on the set temperature of the wafer.

In order to accurately control the temperatures of both a measurement target area and a non-measurement target area of a wafer, it is desirable that the gas regulator include a first gas regulator that regulates the pressure or flow rate of a gas between the plate and the non-measurement target area of the wafer, and a second gas regulator that regulates the pressure or flow rate of a gas between the plate and the measurement target area of the wafer, and that the gas control unit control the first gas manipulated variables input into the first gas regulator using model predictive control based on the estimation temperature of the measurement target area and the estimation temperature of the non-measurement target area and on the set temperature of the non-measurement target area, and control the second gas manipulated variables input into the second gas regulator using model predictive control based on the estimation temperature of the measurement target area and the estimation temperature of the non-measurement target area and on the set temperature of the measurement target area.

In order to accurately estimate the temperature of the non-measurement target area and to accurately control the temperature of the non-measurement target area so that this temperature is maintained at a set temperature, it is desirable that the observer use a state space model in which a heat transfer coefficient between the plate and the wafer is a variable determined from the pressure of the gas.

Here, in the equation of state of the model predictive control, in order to simplify the model and lessen the processing load, using a constant determined from physical property values in the state vector coefficient matrix (A matrix) and the input vector coefficient matrix (B matrix) may be considered.

However, because the rate of heat transfer varies depending on the pressure of the gas supplied between the plate and the wafer, in a model in which the thermal conductivity changes over time, if a constant (i.e., a fixed thermal conductivity) is used for the state vector coefficient matrix (i.e., the A matrix), then it is difficult to accurately maintain the wafer temperature at a set temperature.

For this reason, it is desirable that the gas control unit use, as the predictive model for the model predictive control, a model in which a heat transfer coefficient between the plate and the wafer is a variable determined from the pressure of the gas.

If this type of structure is employed, then it is possible to accurately predict the temperature of a future non-measurement target area, and to then perform control so that the temperature of this non-measurement target area is accurately maintained at a set temperature.

It is comparatively easy to measure the temperature of a circumferential portion (for example an edge portion) of a wafer, and difficult to measure the temperature of a central portion of a wafer. For this reason, it is desirable that the measurement target area be a circumferential portion of the wafer, and that the non-measurement target area be a central portion of the wafer.

In order to measure the temperature of a measurement target area using a simple structure, it is desirable that the temperature sensor be a radiation temperature sensor.

It is desirable that the observer estimate a quantity of heat supplied to the wafer from the outside.

By estimating the quantity of heat supplied from the outside in this way, it is possible to accurately control the temperature of a measurement target area or of a non-measurement target area of a wafer.

Furthermore, a wafer temperature control method according to the present invention is a wafer temperature control method in which a wafer is placed on a temperature-regulated plate and a gas is supplied between the plate and the wafer so that the temperature of the wafer is controlled, and that is characterized in that a pressure or a flow rate of the gas is regulated by a gas regulator, a temperature of either a predetermined measurement target area of the wafer or an area adjacent thereto is measured by a temperature sensor, a temperature of a non-measurement target area that is different from the measurement target area of the wafer is estimated using an observer based on the measurement temperature from the temperature sensor and on a gas manipulated variable input into the gas regulator or the pressure or flow rate regulated by the gas regulator, and the gas manipulated variable input into the gas regulator is controlled using model predictive control based on an estimation temperature for the non-measurement target area estimated by the temperature estimation observer and on a set temperature of the wafer.

Furthermore, a wafer temperature control program according to the present invention is a wafer temperature control program that is used in a wafer temperature control device in which a wafer is placed on a temperature-regulated plate and a gas is supplied between the plate and the wafer so that the temperature of the wafer is controlled, and which is provided with a gas regulator that regulates a pressure or a flow rate of the gas, and a temperature sensor that measures a temperature of either a predetermined measurement target area of the wafer or an area adjacent thereto, and that is characterized by causing a computer to function as an observer that, based on the measurement temperature from the temperature sensor and on a gas manipulated variable input into the gas regulator or the pressure or flow rate regulated by the gas regulator, estimates a temperature of a non-measurement target area that is different from the measurement target area of the wafer, and as a gas control unit that, based on an estimation temperature for the non-measurement target area estimated by the temperature estimation observer and on a set temperature of the wafer, controls the gas manipulated variable input into the gas regulator using model predictive control.

Note that the wafer temperature control program may be delivered electronically, or may be recorded on a program recording medium such as a CD, DVD, or flash memory or the like.

In this way, according to the present invention, by using a device that controls the temperature of a wafer by regulating the pressure or flow rate of a gas, it is possible to control the temperature of, for example, a non-measurement target area where temperature measurement is difficult, so that this area is maintained at a set temperature by measuring, for example, the temperature of either a measurement target area where temperature measurement is possible or an area adjacent thereto.

### BRIEF DESCRIPTION OF THE DRAWINGS

FIG. 1 is a perspective view schematically showing a structure of a wafer temperature control device according to an embodiment of the present invention;

FIG. 2 is a schematic view showing a structure of a gas supply mechanism and control device CTL of the same embodiment;

FIG. 3 is a view showing a relationship between a pressure of a heat transfer gas which is supplied between a wafer and a holding plate, and a heat transfer coefficient between the wafer and the holding plate;

FIG. 4 is a view schematically showing a wafer temperature control system in the same embodiment;

FIG. 5 is a function block diagram of a wafer temperature control device in the same embodiment;

FIG. 6 is a view showing a model predictive control structure of the same embodiment;

FIG. 7 is a view showing a control target model used in the model predictive control of the same embodiment;

FIG. 8 is a view showing a reference trajectory and a prediction trajectory depicted without any distinction being made between two mutually different areas in the model predictive control of the same embodiment;

FIG. 9 is a view showing an equation of state and a reference trajectory of the model predictive control of the same embodiment;

FIG. 10 is a view showing a predictive value obtained from a free response, a predictive value obtained from a step response, and a prediction trajectory of the model predictive control of the same embodiment;

FIG. 11 is a view showing an evaluation function of the model predictive control of the same embodiment;

FIG. 12 is a view showing experiment results and simulation results in a case in which a wafer temperature is controlled using the wafer temperature control device of the same embodiment; and

FIG. 13 is a view showing simulation results in a case in which external disturbance is generated in a case in which a wafer temperature is controlled using the wafer temperature control device of the same embodiment.

### DETAILED DESCRIPTION

### First Embodiment

Hereinafter, an embodiment of a wafer temperature control device according to the present invention will be described with reference made to the drawings.

Note that, in order to facilitate an understanding thereof, each of the drawings described below is depicted schematically with omissions or enhancements made where these are considered appropriate. In addition, identical component elements are allocated the same descriptive symbols, and any duplicated description thereof is omitted where this is considered appropriate.

### 1. Basic Structure of a Wafer Temperature Control Device

A wafer temperature control device 100 of the present embodiment is used in a semiconductor manufacturing device that performs semiconductor manufacturing processing such as, for example, film formation processing or the like, and is formed so as to electrostatically hold in a chuck a rear surface of a wafer W in, for example, a vacuum chamber.

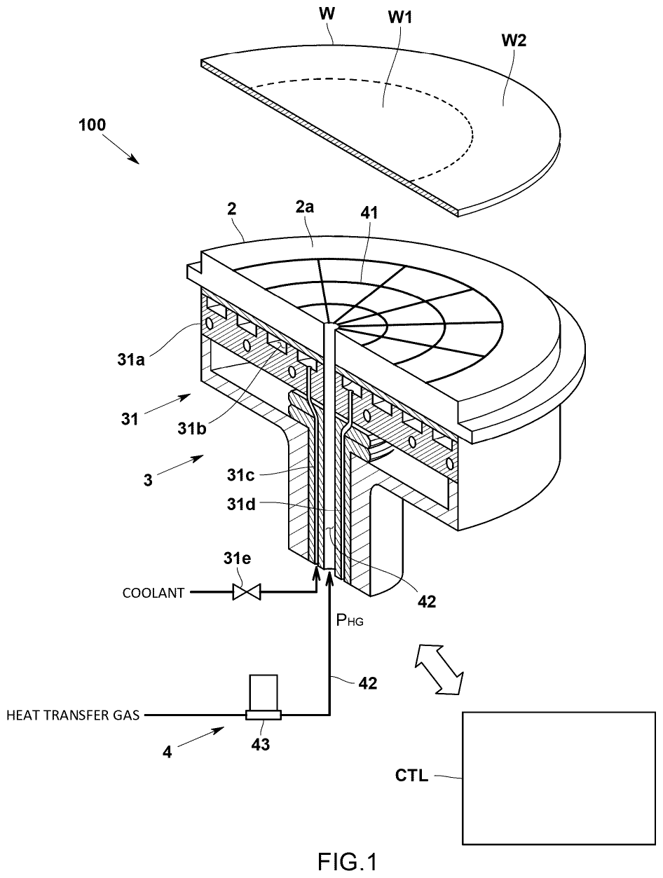

More specifically, as is shown in FIG. 1, the wafer temperature control device 100 is provided with a holding plate 2 on whose upper surface is placed a wafer W, and a temperature regulator 3 that regulates a temperature of the holding plate 2.

The holding plate 2 forms part of what is known as an electrostatic chuck which holds the wafer W using electrostatic holding force. The holding plate 2 of the present embodiment is a ceramic plate having a substantially circular-plate shaped outline, and an upper surface thereof is formed as a holding surface 2a that holds the wafer W. Electrostatic electrodes (not shown in the drawings) that are used to generate electrostatic force between the holding plate 2 and the wafer W are provided within the holding plate 2.

The temperature regulator 3 performs temperature regulation so as to maintain the temperature of the holding plate 2 at a preset temperature, and is provided with a cooler 31 that cools the holding plate 2. Note that it is also possible to employ a structure in which a heater that heats the holding plate 2 is provided as the temperature regulator 3.

The cooler 31 is disposed so as to be in contact with a lower surface of the holding plate 2, and is provided with a base plate 31a that is formed having a substantially circular-plate shaped outline, and a cooling flow path 31b that is formed within the base plate 31a.

The cooling flow path 31b is formed in a spiral configuration when looked at in plan view within the base plate 31a. An inlet flow path 31c and an outlet flow path 31d that are joined to a cooling source such as, for example, a chiller or the like (not shown in the drawings) are connected to the cooling flow path 31b. In addition, a control valve 31e that controls a refrigerant flow rate is provided on a flow path that is connected to the cooling flow path 31b, and a valve aperture of this control valve 31e is controlled by a cooling control unit (not shown in the drawings) of the control device CTL.

### 2. Gas Supply Mechanism 4

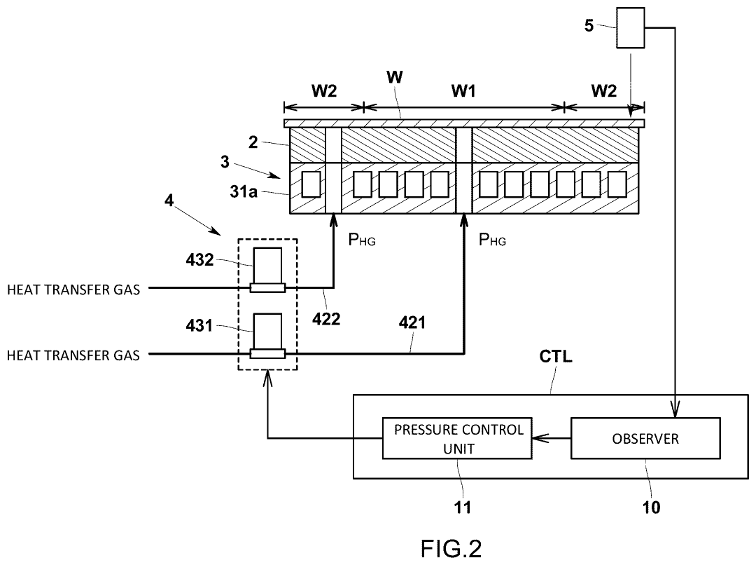

Moreover, as is shown in FIG. 1 and FIG. 2, the wafer temperature control device 100 of the present embodiment is provided with a gas supply mechanism 4 that supplies a gas that transfers heat such as, for example, helium gas or argon gas or the like (referred to below as a heat transfer gas) between the holding plate 2 and the wafer W.

This gas supply mechanism 4 supplies heat transfer gas at a predetermined pressure between the holding surface 2a of the holding plate 2 and the rear surface of the wafer W that is being held thereon.

More specifically, as is shown in FIG. 1, the gas supply mechanism 4 includes gas distribution grooves 41 that are formed in the holding surface 2a of the holding plate 2, a gas supply path 42 that supplies the heat transfer gas to the gas distribution grooves 41, and a pressure regulator 43 which is a gas regulator that regulates the pressure of the heat transfer gas supplied to the gas distribution grooves 41. The heat transfer gas supplied to the gas distribution grooves 41 flows from these gas distribution grooves 41 to a position between the holding surface 2a of the holding plate 2 and the rear surface of the wafer W that is being held thereon.

The gas distribution grooves 41 include, for example, a plurality of rectilinear grooves that are formed extending out in a radial pattern from a central axis of the holding plate 2, and a plurality of circular grooves that are formed in progressively larger concentric circles around the central axis of the holding plate 2.

As is shown in FIG. 2, the gas supply path 42 includes a first gas supply path 421 that supplies heat transfer gas to a central portion of the holding surface 2a of the holding plate 2, and a second gas supply path 422 that supplies heat transfer gas to a circumferential portion of the holding surface 2a of the holding plate 2. Note that the central portion of the holding surface 2a (this central portion corresponds to a central portion W1, which is a non-measurement target area of the wafer W) is formed in a circular shape, while the circumferential portion of the holding surface 2a (this circumferential portion corresponds to the circumferential portion W2, which is a measurement target area of the wafer W) is formed in an annular shape. Both the first gas supply path 421 and the second gas supply path 422 are connected to a heat transfer gas source (not shown in the drawings).

As is shown in FIG. 2, the pressure regulator 43 includes a first pressure regulator 431, which is provided on the first gas supply path 421 and is a first gas regulator that regulates the pressure of the heat transfer gas supplied to the central portion of the holding surface 2a, and a second pressure regulator 432, which is provided on the second gas supply path 422 and is a second gas regulator that regulates the pressure of the heat transfer gas supplied to the circumferential portion of the holding surface 2a.

The first pressure regulator 431 regulates the pressure of the heat transfer gas between the holding plate 2 and the central portion W1, which is the non-measurement target area of the wafer W, by regulating the pressure of the heat transfer gas supplied to the central portion of the holding surface 2a. Moreover, the second pressure regulator 432 regulates the pressure of the heat transfer gas between the holding plate 2 and the circumferential portion W2, which is the measurement target area of the wafer W, by regulating the pressure of the heat transfer gas supplied to the circumferential portion of the holding surface 2a.

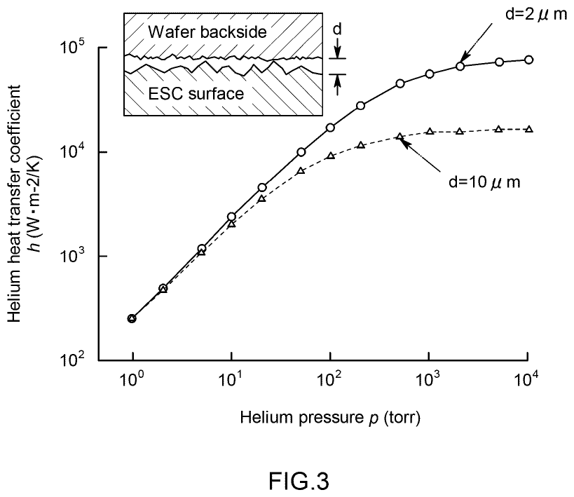

Each of the pressure regulators 431 and 432 is able to vary the rate of heat transfer from the holding plate 2 to the wafer W (i.e., the heat transfer coefficient between the wafer W and the holding plate 2) by regulating the pressure of the heat transfer gas. Note that FIG. 3 shows a relationship between the pressure of the heat transfer gas supplied between the wafer W and the holding plate 2, and the heat transfer coefficient between the wafer W and the holding plate 2. The heat transfer coefficient of the present embodiment has a non-linear relationship in accordance with the pressure of the heat transfer gas, however, it is also possible for the heat transfer coefficient of the present embodiment to have a linear relationship.

More specifically, each pressure regulator 43 has a pressure sensor and a pressure control valve, and a valve aperture thereof is controlled by a pressure control unit 12 which is a gas control unit (described below) of the control device CTL.

Moreover, as is shown in FIG. 2, the wafer temperature control device 100 is also provided with a temperature sensor 5 that measures a temperature of the circumferential portion W2, which is a predetermined measurement target area of the wafer W, or of an area adjacent thereto. The temperature sensor 5 of the present embodiment is an infrared sensor such as, for example, a radiation thermometer or the like that measures the temperature of the circumferential portion W2 of the wafer W. In a case in which a radiation thermometer is used as the temperature sensor 5, then measuring the temperature of the circumferential portion W2 of the wafer W through an optical window provided in a side wall of a vacuum chamber may be considered. Note that it is also possible to use a sensor that is disposed on the base plate 31a or on the holding plate 2 as the temperature sensor 5, and that measures the temperature of the base plate 31a or the holding plate 2 as the adjacent temperature of the wafer W.

### 3. Wafer Temperature Control System

Furthermore, the wafer temperature control device 100 is also provided with the control device CTL that controls operations of at least the temperature regulator 3 and the respective pressure regulators 431 and 432.

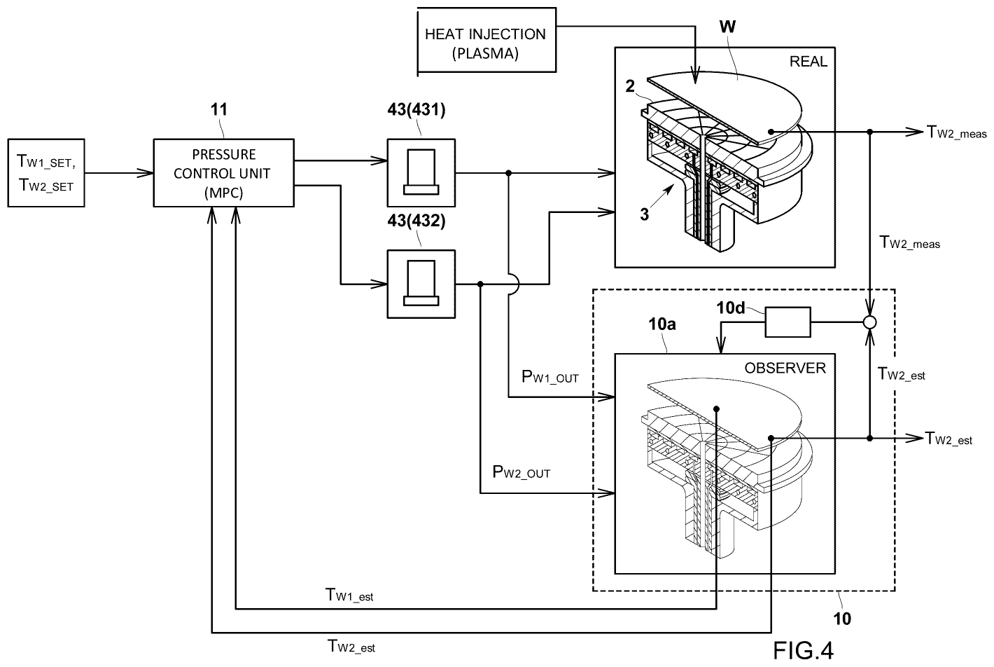

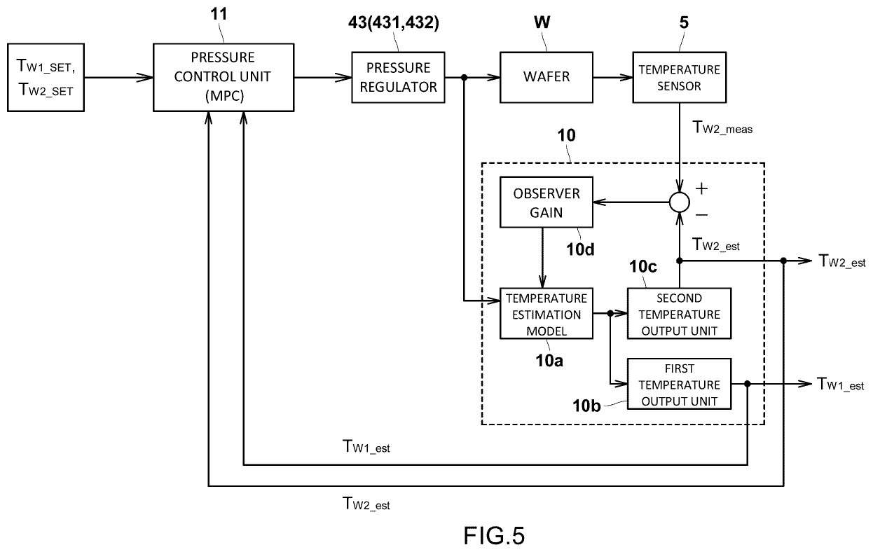

Note that the control device CTL is what is commonly called a computer that is provided with a CPU, memory, an A/D converter, a D/A converter, and various types of input/output devices. A wafer temperature control system such as is shown in FIG. 4 and FIG. 5 is constructed as a result of a wafer temperature control program stored in the memory being executed so as to enable the various devices to operate in mutual collaboration.

Firstly, an outline of the wafer temperature control system of the present embodiment will be described with reference to FIG. 4 and FIG. 5.

In the present embodiment, a valve aperture of the control valve 31e of the cooler 31 is controlled so as to be kept uniform irrespective of estimation temperatures T_{W1_est} and T_{W2_est} of the central portion W1 and the circumferential portion W2 of the wafer W that are estimated by an observer 10, and of a measurement temperature T_{W2_meas} of the circumferential portion W2 that is measured by the temperature sensor 5. In other words, a cooling manipulated variable during an operation is fixed, and the amount of temperature regulation per unit time performed by the temperature regulator 3 is controlled so as to remain constant.

In contrast to this, pressure manipulated variables input into the respective pressure regulators 431 and 432 are sequentially altered based on the estimation temperatures T_{W1_est} and T_{W2_est} of the central portion W1 and the circumferential portion W2 estimated by the observer 10, and on the measurement temperature T_{W2_meas} of the circumferential portion W2 that is measured by the temperature sensor 5.

More specifically, the control device CTL estimates the respective temperatures T_{W1_est} and T_{W2_est} of the central portion W1 and the circumferential portion W2 of the wafer W using the observer 10 based on the measurement temperature T_{W2_meas} of the circumferential portion W2 that is measured by the temperature sensor 5. In addition, the control device CTL performs feedback control on the respective estimation temperatures T_{W1_est} and T_{W2_est} of the central portion W1 and the circumferential portion W2, and controls the respective pressure regulators 431 and 432 so that the respective estimation temperatures T_{W1_est} and T_{W2_est} track respective set temperatures T_{W1_SET} and T_{W2_SET}.

More specifically, as is shown in FIG. 4 and FIG. 5, the control device CTL is provided with the observer 10 that estimates the temperatures T_{W1_est} and T_{W2_est} of the central portion W1 and the circumferential portion W2 of the wafer W, and with a pressure control unit 11 that performs feedback control on the respective pressure regulators 431 and 432 based on the set temperatures T_{W1_SET} and T_{W2_SET} of the central portion W1 and the circumferential portion W2 of the wafer W, and on the respective estimation temperatures T_{W1_est} and T_{W2_est} of the central portion W1 and the circumferential portion W2 estimated by the observer 10.

### [3-1. Observer 10]

The observer 10 simulates at least the thermal behavior of the system, and estimates the temperatures T_{W1_est} and T_{W2_est} of the central portion W1, which is a non-measurement target area, and the circumferential portion W2, which is a measurement target area.

More specifically, the observer 10 is formed so as to output the estimation temperature T_{W1_est}, which is an estimated value of the temperature of the central portion W1, and the estimation temperature T_{W2_est}, which is an estimated value of the temperature of the circumferential portion W2 based on the measurement temperature T_{W2_meas} of the circumferential portion W2 that is measured by the temperature sensor 5 and on respective pressures P_{W1_OUT} and P_{W2_OUT} that are output by the respective pressure regulators 431 and 432.

More specifically, as is shown in FIG. 5, the observer 10 is provided with a temperature estimation model 10a which is either a linear or non-linear state space model whose output variables are formed by a temperature T_{W1} of the central portion W1 and a temperature T_{W2} of the peripheral portion of the wafer W, a first temperature output unit 10b that outputs the estimation temperature T_{W1_est} of the central portion W1 that was estimated based on the temperature estimation model 10a, a second temperature output unit 10c that outputs the estimation temperature T_{W2_est} of the circumferential portion W2 that was estimated based on the temperature estimation model 10a, and an observer gain 10d.

In addition, the observer 10 is formed such that a value obtained by multiplying the observer gain 10d by a deviation between the estimation temperature T_{W2_est} of the circumferential portion W2 output from the second temperature output unit 10c and the measurement temperature T_{W2_meas} of the circumferential portion W2 measured by the temperature sensor 5 is fed back into the temperature estimation model 10a.

The temperature estimation model 10a is created, for example, by modeling the heat conductions of the actual holding plate 2 and wafer W themselves, and the heat transfer between the holding plate 2 and the wafer W.

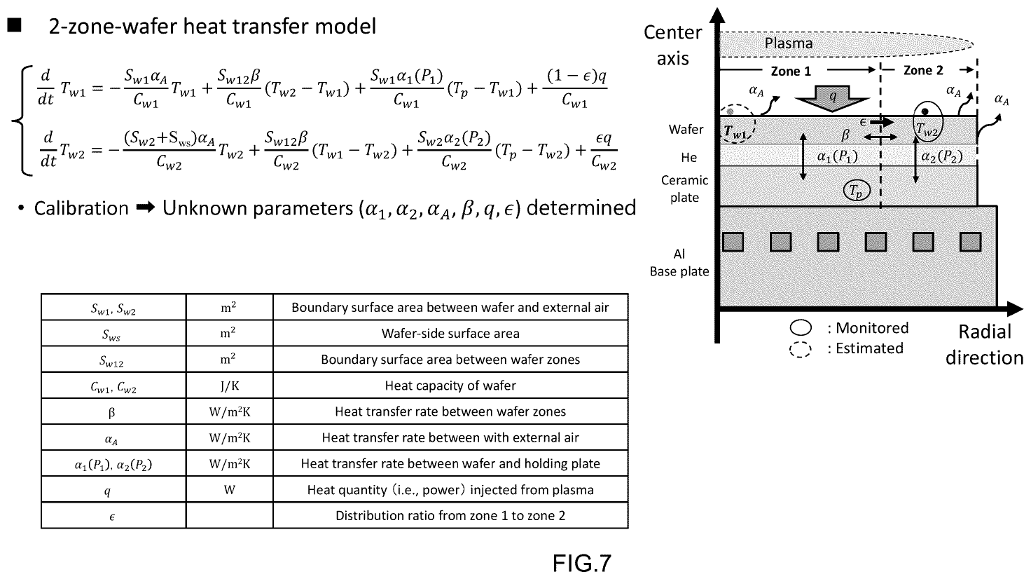

The temperature estimation model 10a is state space model in which a relationship between at least the temperature T_{W} of the wafer W and a pressure P_{HG} of the heat transfer gas is made either linear or non-linear. In the present embodiment, as is shown in FIG. 7, the state space model used for the temperature estimation model 10a is the same non-linear model as the predictive model (control target model) of the pressure control unit 11 (described below). The input variables of the temperature estimation model 10a of the present embodiment are not only respective pressures P_{W1_OUT} and P_{W2_OUT} (shown as P₁ and P₂ in FIG. 7) output from the respective pressure regulators 43, but also include the cooling quantities from the cooler 31 (i.e., a temperature Tₚ of the holding plate 2 or the base plate 31a) or the heat quantities (shown as q in FIG. 7) supplied from the outside (for example, from plasma) to the wafer W.

More specifically, as is shown in FIG. 5, the temperature estimation model 10a receives inputs of input variable vectors including respective pressures P_{W1_OUT} and P_{W2_OUTT} and the like output from the respective pressure regulators 431 and 432, and state variable vectors including the estimation temperature T_{W1_est} of the central portion W1 and the estimation temperature T_{W2_est} of the circumferential portion W2.

The first temperature output unit 10b extracts the estimation temperature T_{W1_est} of the central portion W1 from the output from the temperature estimation model 10a, and outputs this to the pressure control unit 11.

The second temperature output unit 10c extracts the estimation temperature T_{W2_est} of the circumferential portion W2 from the output from the temperature estimation model 10a, and then outputs this. The deviation between the output estimation temperature T_{W2_est} of the circumferential portion W2 and the measurement temperature T_{W2_meas} of the circumferential portion W2 measured by the temperature sensor 5 is calculated, and input into the observer gain 10d.

### [3-2. Pressure Control Unit 11]

The pressure control unit 11 controls the respective pressure regulators 431 and 432 that regulate the pressure P_{HG} of the heat transfer gas using model predictive control based on the set temperature T_{SET} of the wafer W, and on the estimation temperatures T_{W1_est} and T_{W2_est} estimated by the observer 10.

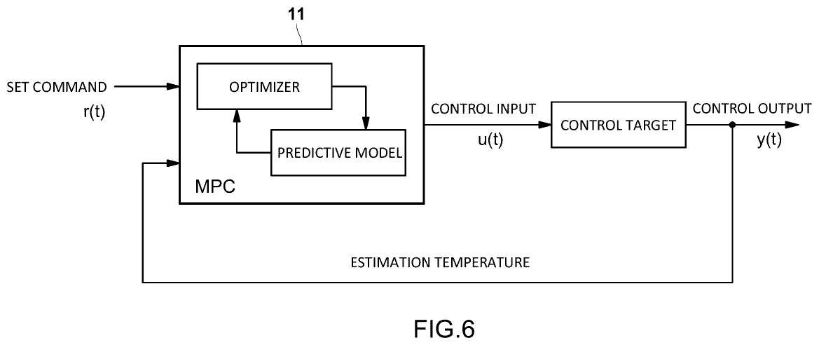

Here, as is shown in FIG. 6, model predictive control is a control method in which optimization is performed at the same time as future responses at each point in time are predicted. By providing a predictive model (i.e., a control target model) within the pressure control unit 11, future behavior of the control target over a particular limited period of time from the current point in time is predicted.

In FIG. 6, a set command r(t) is formed by the respective set temperatures for the central portion W1 and the circumferential portion W2 of the wafer W, a control input u(t) is formed by a pressure manipulated variable which is the gas manipulated variable input into the respective pressure regulators 431 and 432, and a control output y(t) is formed by the estimation temperatures T_{W1_est} and T_{W2_est} of the central portion W1 and the circumferential portion W2 that have been estimated by the observer 10. The estimation temperatures T_{W1_est} and T_{W2_est} of the observer 10 are applied to the predictive model within the pressure control unit 12, and a new control input u(t) is determined so as to minimize tracking errors within a predetermined time from the current time in the optimizer.

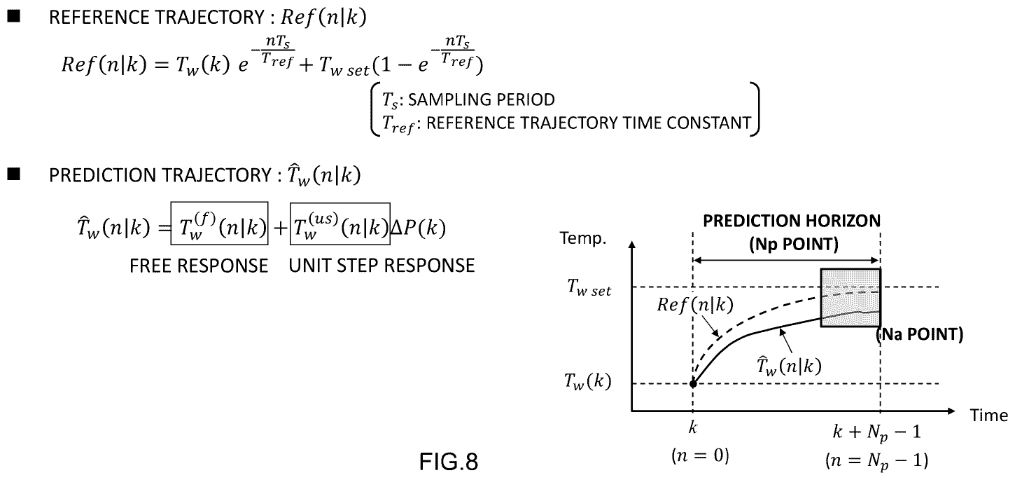

A control target model used in this model predictive control is shown in FIG. 7. In the control target model of the present embodiment, two heat areas are set in a concentric configuration. One heat area (Zone 1) is formed in a circular configuration and is located in the central portion W1, while the other heat area (Zone 2) is formed in an annular configuration and is located in the circumferential portion (i.e., in an outer peripheral portion) W2. Note that, as is described above, the control target model used in the model predictive control is the same non-linear model as the temperature estimation model 10a of the observer 10. In addition, in the holding plate 2, the set temperature of the heating area of the central portion W1 is T_{W1_SET}, and the set temperature of the heating area of the circumferential portion W2 is T_{W2_SET}. Note that, in FIG. 8, a reference trajectory and a prediction trajectory that are depicted without any distinction being made between two mutually different areas are shown.

In the control target model shown in FIG. 7, changes over time in the wafer temperature T_{W1} of Zone 1 and changes over time in the wafer temperature T_{W2} of Zone 2 can be shown by heat radiation to the outside, heat conduction between zones, heat transfer between layers, and heat supplied from the outside. Note that the heat radiation is proportional to the fourth power of the temperature, however, this item is a small value in itself and in order to simplify the calculation, here, is set as a first power where appropriate.

More specifically, as has been stated above, the pressure control unit 12 uses, as the predictive model for the model predictive control (i.e., as the control target model), a model in which a heat transfer coefficient between the holding plate 2 and the wafer W is a variable determined from the pressure P_{HG} of the heat transfer gas. More specifically, the output control unit 12 controls the pressure manipulated variables input into the respective pressure regulators 431 and 432 using model predictive control based on the estimation temperatures T_{W1_est} and T_{W2_est} of the central portion W1 and the circumferential portion W2 that are estimated by the observer 10, and on the set temperatures T_{W1_SET} and T_{W2_SET} of the central portion W1 and the circumferential portion W2.

Here, the pressure control unit 12 controls the pressure manipulated variables using an equation of state in which pressures P₁ and P₂ of the heat transfer gas are included as parameters in the state vector coefficient matrix (i.e., the A matrix) in the model predictive control. In this case, the reason why the pressures P₁ and P₂ of the heat transfer gas are included in the state vector coefficient matrix (i.e., the A matrix) is because the heat transfer rates α₁ (P₁) and α₂ (P₂) between the wafer and the holding plate are changed by the pressures P₁ and P₂ of the heat transfer gas.

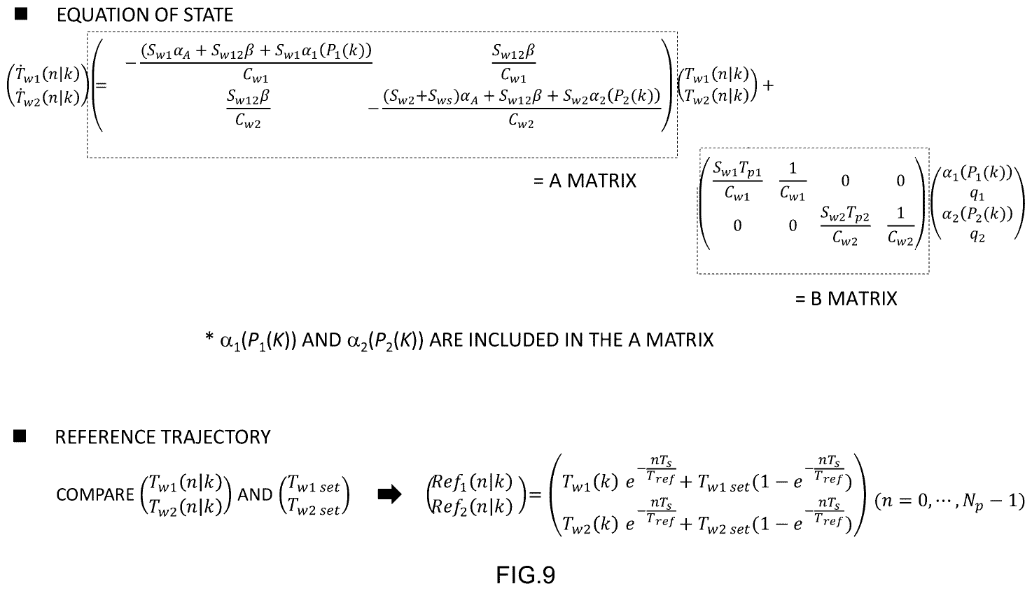

More specifically, the pressure control unit 12 uses the equation of state shown in FIG. 9.

In this equation of state, the coefficient matrix of the state vector (i.e., the A matrix) is a matrix that shows the thermal conductivity and the heat capacity in each divided area (i.e., zone), and contains the heat transfer rates α₁ (P₁) and α₂ (P₂) between the wafer W and the holding plate 2 determined from the pressures P₁ and P₂ of the heat transfer gas. In addition, the coefficient matrix of the input vector in the equation of state (i.e., the B matrix) is a matrix that shows a coefficient for converting the heat transfer rates α₁ (P₁) and α₂ (P₂) between the wafer and the holding plate, and heat quantities (i.e., electrical power) q₁ and q₂ that are injected from plasma into temperature changes. Furthermore, the reference trajectory in the model predictive control shows an ideal trajectory that exponentially approaches the set temperature from the temperature at the current point in time, and is shown in FIG. 8.

Next, the pressure control unit 12 calculates a coefficient matrix (i.e., an A matrix) each time a prediction trajectory is calculated for the temperature of the wafer W in the model predictive control, and then using the coefficient matrix (i.e., the A matrix) updated by this calculation, calculates the next prediction trajectory.

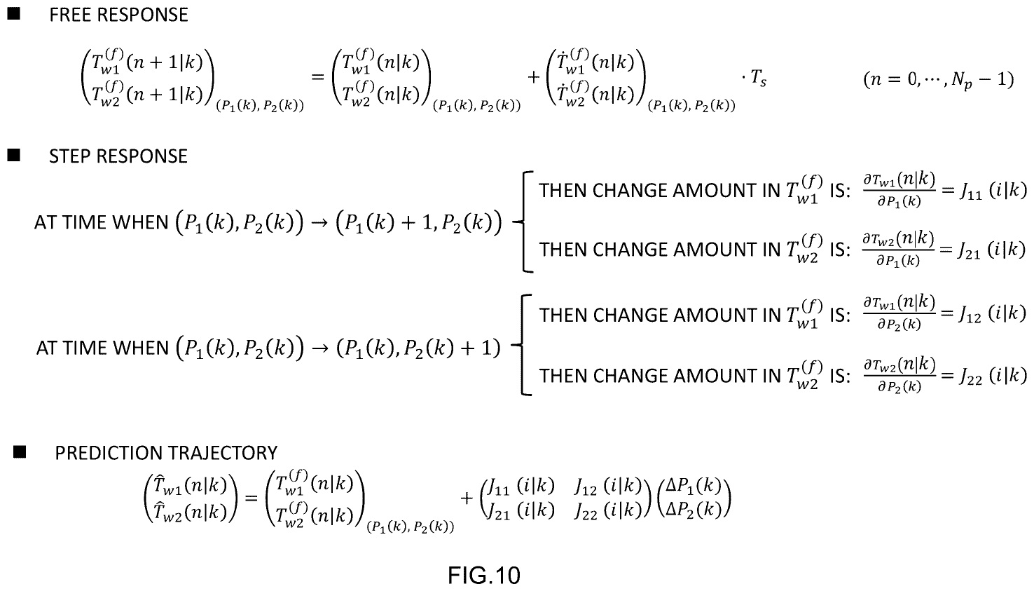

More specifically, as is shown in FIG. 9 and FIG. 10, the pressure control unit 12 calculates a prediction trajectory determined from the equation of state. Even more specifically, the pressure control unit 12 calculates the prediction trajectory using prediction values obtained using free response, and prediction values obtained using step response.

The prediction values obtained using free response show a trajectory of a subsequent Np number of steps from when the inputs P₁(k) and P₂(k) are in effect at the current time (i.e., at the time k).

The prediction values obtained using step response show a difference (i.e., a change amount) between current temperatures T_{W1}(k) and T_{W2}(k) and the trajectory of the subsequent Np number of steps in a case in which the input P₁(k) is set at P₁(k)+1, and in a case in which the input P₂(k) is set at P₂(k)+1.

Here, because the inputs P₁(k) and P₂(k) are updated sequentially, it is necessary for these to be determined by calculation each time. The inputs P₁(k) and P₂(k) used for the prediction values obtained using step response are pressure manipulated variables input into the respective pressure regulators 431 and 432, or are the pressures that are regulated by the respective pressure regulators 431 and 432.

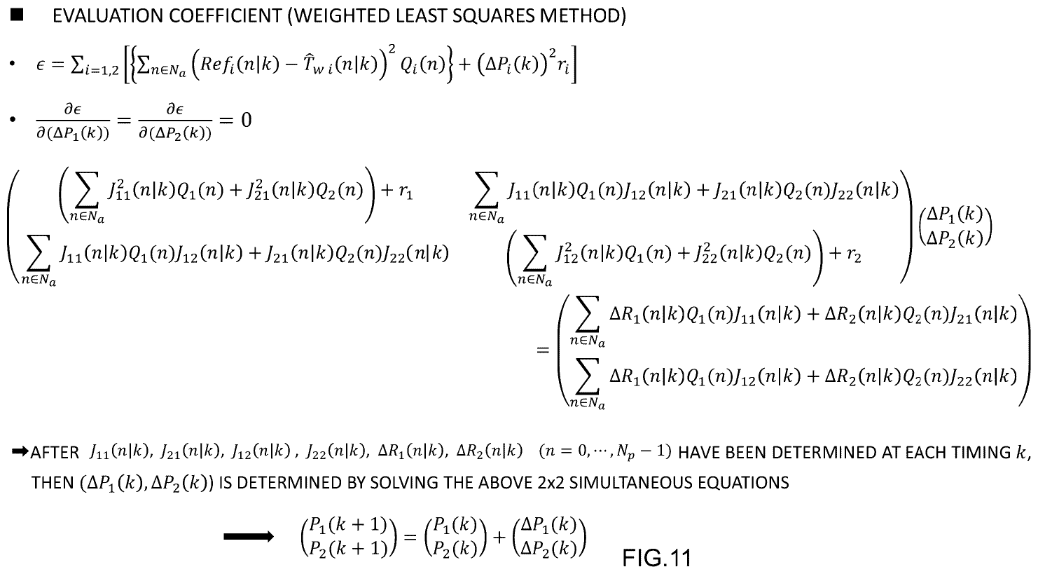

Next, as is shown in FIG. 11, the pressure control unit 12 determines pressure manipulated variables so as to optimize an evaluation coefficient that utilizes a weighted least squares method relating to a deviation between the reference trajectory for the temperature of the wafer W and the prediction trajectory for the temperature of the wafer W in the model predictive control. Note that, in the evaluation coefficient, in order to prevent hunting from occurring, terms r₁ and r₂, which reduce the pressure are added, and these terms r₁ and r₂ are made as small as possible. In this way, by using a weighted least squares method as an evaluation coefficient, an iterative calculation is rendered unnecessary, and it is possible to reduce the calculation quantity. Note that, in a case in which the evaluation coefficient is not able be solved analytically due to the restrictions of constraint conditions or the like, then it is also possible to use a method that employs an exploratory solving method such as a shooting method, a gradient descent method, or Newton's method or the like.

### 4. Experiment Results and Simulation Results

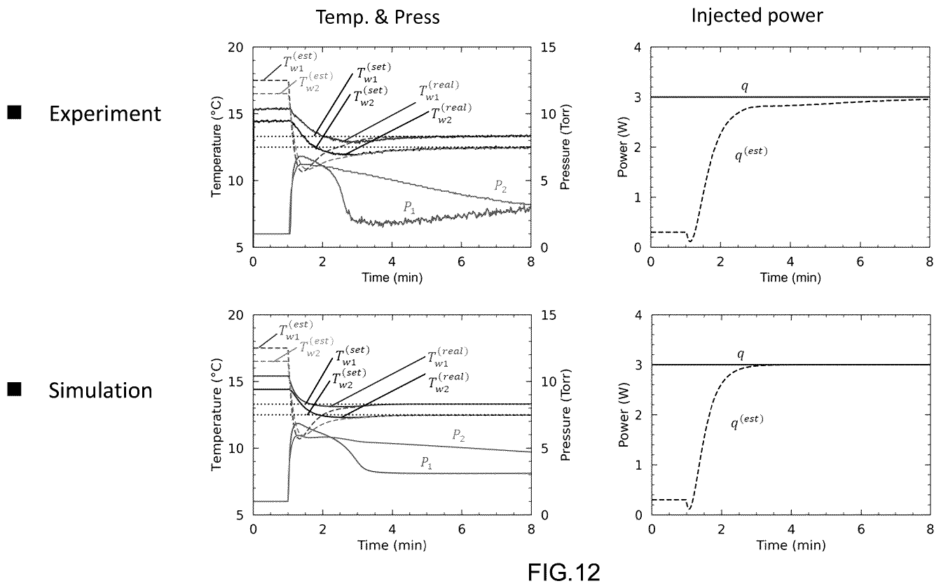

Next, test results and simulation results in a case in which the temperature of a wafer W is controlled using the wafer temperature control device 100 of the present embodiment are shown in FIG. 12. Note that, each time a test was performed, the amount of heat supplied to the wafer W from the outside was reproduced using a halogen lamp.

In each set of results, the temperatures of the central portion W1 and the circumferential portion W2 of the wafer W were accurately controlled so as to be maintained at the set temperature by controlling the pressure manipulated variables input into the respective pressure regulators 431 and 432 using model predictive control based on the estimated temperatures T_{W1_est} and T_{W2_est} for the central portion W1 and the circumferential portion W2, and on the set temperatures T_{W1_SET} and T_{W2_SET} for the central portion W1 and the circumferential portion W2. Moreover, it was found that the heat quantity injected into the wafer W (i.e., the injected power) can also be estimated by the observer 10. Note that, in FIG. 12, q denotes a fixed heat quantity (i.e., is a set value), while qₑₛₜ denotes an estimated heat quantity.

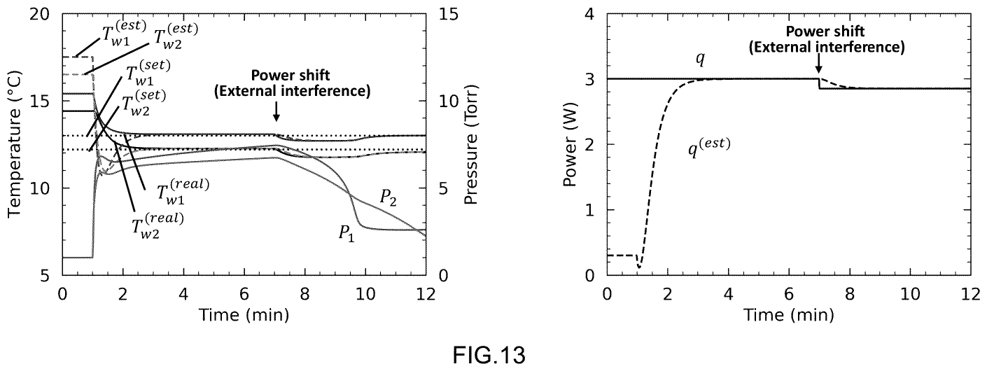

Moreover, simulation results in a case in which external disturbance acted on the wafer W in the above-described test or simulation are shown in FIG. 13. Note that the external disturbance acting on the wafer W was reproduced by varying the heat quantity (i.e., by performing power shifting) supplied from the outside to the wafer W.

In these simulation results, even if there is external disturbance, by controlling the pressure manipulated variables input into the respective pressure regulators 431 and 432 using model predictive control based on the estimated temperatures T_{W1_est} and T_{W2_est} for the central portion W1 and the circumferential portion W2, and on the set temperatures T_{W1_SET} and T_{W2_SET} for the central portion W1 and the circumferential portion W2, it is possible to accurately control the temperatures of the central portion W1 and the circumferential portion W2 of the wafer W such that these are maintained at the set temperature. In other words, the wafer temperature control device 100 of the present embodiment is able to perform robust control even of external disturbance generated by plasma or the like that injects heat into the wafer.

### 5. Effects Provided by the Present Embodiment

According to the wafer temperature control device 100 of the present embodiment, because the temperature of a non-measurement target area (i.e., the central portion W1) of a wafer W is estimated using the observer 10 whose input variables are the measurement temperature of a measurement target area (i.e., the circumferential portion W2) of the wafer W and the pressure of the heat transfer gas, it is possible to estimate with a sufficient degree of accuracy the temperature of the non-measurement target area (i.e., the central portion W1) of the wafer W. In addition, because the pressure manipulated variables input into the respective pressure regulators 431 and 432 are controlled using model predictive control based on the estimated temperature for the non-measurement target area (i.e., the central portion W1) estimated by the observer 10, and on the set temperature of the wafer W, it is easy to incorporate non-linear behavior of the rate of heat transfer from the holding plate 2 to the wafer W, and the temperature of the non-measurement target area (i.e., the central portion W1) of the wafer W can be accurately controlled so as to be maintained at the set temperature.

By combining the observer 10 and model predictive control (i.e., MPC) in this way, it is possible to accurately control the temperature of the non-measurement target area (i.e., the central portion W1) of the wafer W simply by measuring the temperature of the measurement target area (i.e., the circumferential portion W2) of the wafer W. In other words, simply by measuring the temperature of a single location of a wafer, it is possible to accurately control the temperature of another location, and to thereby improve usability. In addition, by combining the observer 10 and model predictive control (MPC) in this way, it is possible to perform robust control even of external disturbance generated by plasma or the like that injects heat into the wafer.

### 6. Additional Embodiments

For example, in the above-described embodiment, the temperature sensor 5 measures the temperature of the circumferential portion W2 of a wafer W, however, it is also possible for the temperature of an area adjacent to the circumferential portion W2 of the wafer W to be measured. In this case, the observer 10 estimates the temperature of the central portion W1 and the circumferential portion W2 of the wafer W based on the measurement temperatures (i.e., the adjacent temperatures) from the temperature sensor and on the pressure manipulated variables input into the respective pressure regulators 431 and 432 or the pressures P_{W1_OUT} and P_{W2_OUT} regulated by the pressure regulators 431 and 432.

Moreover, the pressure control unit 11 of the above-described embodiment performs MPC on the respective pressure regulators 431 and 432 using the estimation temperatures T_{W1_est} and T_{W2_est} for the central portion W1 and the circumferential portion W2, however, it is also possible for MPC to be performed on the respective pressure regulators 431 and 432 using the estimation temperature T_{W1_est} for the central portion W1 and the measurement temperature T_{W2_meas} for the circumferential portion W2.

Furthermore, in the above-described embodiment, the measurement target area is the circumferential portion W2 and the non-measurement target area is the central portion W1, however, these may also be reversed. In addition, it is also possible for the measurement target area to be an optional location of a wafer, and for the non-measurement target area to be an optional location other than the measurement target area.

In the above-described embodiment, a plurality of areas where the set temperatures for the wafer W are mutually different from each other are set in the holding plate 2 by varying the pressure of the heat transfer gas within the surface of the holding plate 2, however, it is also possible to leave the pressure of the heat transfer gas within the surface of the holding plate 2 unchanged, and to set a single set temperature in the entire holding plate 2.

The temperature regulated areas of the wafer W and the holding plate 2 are not limited to being set as two areas in each (i.e., as the central portion and the circumferential portion), and it is also possible for a greater number of areas to be set in each.

Moreover, it is also possible to employ a structure in which the holding plate 2 is not provided with a holding function but is, instead, simply a plate on top of which the wafer W is placed.

The wafer temperature control device 100 of the above-described embodiment controls the temperature of the wafer W by regulating the pressure of the heat transfer gas using the pressure regulators 431 and 432, however, it is also possible to control the temperature of the wafer W by regulating the flow rate of the heat transfer gas. In order to achieve this, the wafer temperature control device 100 may be provided with a flow rate regulator in the form of a gas regulator that regulates the flow rate of a thermoelectric voltage gas, the temperature sensor 5 that measures the temperature of the predetermined measurement target area W2 of the wafer W or of an area adjacent thereto, the observer 10 that estimates the temperature of the non-measurement target area W1, which is different from the measurement target area W2, of the wafer W, based on the measurement temperature from the temperature sensor 5 and on flow rate manipulated variables, which are gas manipulated variables input into the flow rate regulator, or the flow rate regulated by the flow rate regulator, and a flow rate control unit which is a gas control unit that controls the flow rate manipulated variables input into the flow rate regulator using model predictive control based on the estimation temperature for the non-measurement target area W1 estimated by the observer 10 and on the set temperature for the wafer W.

The structures of the cooler and the heater are not limited to those described above. For example, the cooler may be formed using a Peltier element or the like, while the heater is not limited to being a heater electrode and may instead be formed so as to heat a wafer using light irradiation, or in such a way that a wafer is heated by plasma.

Furthermore, it should be understood that the present invention is not limited to the above-described embodiments, and that various modifications and the like may be made thereto insofar as they do not depart from the spirit or scope of the present invention.

### DESCRIPTION OF THE REFERENCE CHARACTERS

100 . . . Wafer Temperature Control Device
W . . . Wafer
W1 . . . Central Portion (Non-Measurement Target Area)
W2 . . . Peripheral Portion (Measurement Target Area)
2 . . . Holding Plate (Plate)
3 . . . Temperature Regulator
43 . . . Pressure Regulator (Gas Regulator)
431 . . . First Pressure Regulator (First Gas Regulator)
432 . . . Second Pressure Regulator (Second Gas Regulator)
5 . . . Temperature Sensor
10 . . . Observer
11 . . . Pressure Control Unit (Gas Control Unit)

What is claimed is:

1. A wafer temperature control device in which a wafer is placed on a temperature-regulated plate and a gas is supplied between the plate and the wafer so as to control the temperature of the wafer, comprising:
a gas regulator that regulates a pressure or a flow rate of the gas;
a temperature sensor that measures a temperature of either a predetermined measurement target area of the wafer or an area adjacent thereto;
an observer that, based on the measurement temperature from the temperature sensor and on a gas manipulated variable input into the gas regulator or the pressure or flow rate regulated by the gas regulator, estimates a temperature of a non-measurement target area that is different from the measurement target area of the wafer; and
a gas control unit that, based on an estimation temperature for the non-measurement target area estimated by the observer and on a set temperature for the wafer, controls the gas manipulated variable input into the gas regulator using model predictive control.

2. The wafer temperature control device according to claim 1, wherein the observer estimates not only the temperature of the non-measurement target area but also a temperature of the measurement target area, and
the gas control unit controls the gas manipulated variable input into the gas regulator using model predictive control based on the estimation temperature of the measurement target area and the estimation temperature of the non-measurement target area and on the set temperature of the wafer.

3. The wafer temperature control device according to claim 2, wherein the gas regulator comprises:
a first gas regulator that regulates the pressure or flow rate of a gas between the plate and the non-measurement target area of the wafer; and
a second gas regulator that regulates the pressure or flow rate of a gas between the plate and the measurement target area of the wafer, and
the gas control unit controls
the first gas manipulated variable input into the first gas regulator using model predictive control based on the estimation temperature of the measurement target area and the estimation temperature of the non-measurement target area and on the set temperature of the non-measurement target area, and controls
the second gas manipulated variable input into the second gas regulator using model predictive control based on the estimation temperature of the measurement target area and the estimation temperature of the non-measurement target area and on the set temperature of the measurement target area.

4. The wafer temperature control device according to claim 1, wherein the observer uses a state space model in which a heat transfer coefficient between the plate and the wafer is a variable determined from the pressure of the gas.

5. The wafer temperature control device according to claim 1, wherein the pressure control unit uses, as the predictive model for the model predictive control, a model in which a heat transfer coefficient between the plate and the wafer is a variable determined from the pressure of the gas.

6. The wafer temperature control device according to claim 1, wherein
the measurement target area is a circumferential portion of the wafer, and
the non-measurement target area is a central portion of the wafer.

7. The wafer temperature control device according to claim 1, wherein the temperature sensor is a radiation temperature sensor.

8. The wafer temperature control device according to claim 1, wherein the observer estimates a quantity of heat supplied to the wafer from the outside.

9. A wafer temperature control method in which a wafer is placed on a temperature-regulated plate and a gas is supplied between the plate and the wafer so that the temperature of the wafer is controlled, and in which:
a pressure or a flow rate of the gas is regulated by a gas regulator;
a temperature of either a predetermined measurement target area of the wafer or an area adjacent thereto is measured by a temperature sensor;
a temperature of a non-measurement target area that is different from the measurement target area of the wafer is estimated using an observer based on the measurement temperature from the temperature sensor and on a gas manipulated variable input into the gas regulator or the pressure or flow rate regulated by the gas regulator; and
the gas manipulated variable input into the gas regulator is controlled using model predictive control based on an estimation temperature for the non-measurement target area estimated by the observer and on a set temperature of the wafer.

10. A non-transitory computer-readable medium storing a wafer temperature control program that is used in a wafer temperature control device in which a wafer is placed on a temperature-regulated plate and a gas is supplied between the plate and the wafer so that the temperature of the wafer is controlled, and which is provided with a gas regulator that regulates a pressure or a flow rate of the gas, and a temperature sensor that measures a temperature of either a predetermined measurement target area of the wafer or an area adjacent thereto, the program executable by a computer to cause the computer to function as:
an observer that, based on the measurement temperature from the temperature sensor and on a gas manipulated variable input into the gas regulator or the pressure or flow rate regulated by the gas regulator, estimates a temperature of a non-measurement target area that is different from the measurement target area of the wafer; and
a gas control unit that, based on an estimation temperature for the non-measurement target area estimated by the observer and on a set temperature of the wafer, controls the gas manipulated variable input into the gas regulator using model predictive control.
